(19) United States
(12) Patent Application Publication
(10) Pub. No.: US 2026/0048981 A1
(43) Pub. Date: Feb. 19, 2026

(54) MEMS Resonator with Co-packaged Thermistor

(71) Applicant: Stathera IP Holdings Inc., Montreal (CA)

(72) Inventors: Christophe Sabourin, Montreal (CA); Reuble Mathew, Saint-Lambert (CA); Adrian Dybka, Montreal (CA)

(21) Appl. No.: 19/233,282

(22) Filed: Jun. 10, 2025

Related U.S. Application Data
(60) Provisional application No. 63/684,253, filed on Aug. 16, 2024.

(51) Int. Cl. B81B 7/02; B81C 3/00; G01K 7/22

(52) U.S. Cl. CPC B81B 7/02; B81C 3/001; G01K 7/223; G01K 7/226; B81B 2201/0278; B81B 2203/0307; B81B 2203/0315; B81B 2203/033; B81B 2203/04; B81C 2201/0132; B81C 2201/0171; B81C 2203/0118; B81C 2203/036

(57) ABSTRACT

MEMS devices with co-packaged thermistors and methods of fabrication are described in which a support layer is patterned to include a lower cavity and a thermistor pattern spanning directly underneath the lower cavity. A device layer is bonded to the patterned support layer and includes a resonator element that is over the lower cavity. A cap layer bonded to the device layer.

### RELATED APPLICATIONS

This application claims the benefit of priority from U.S. Provisional Patent Application Ser. No. 63/684,253 filed on Aug. 16, 2024, the full disclosure of which is incorporated herein by reference.

### BACKGROUND

### Field

Embodiments described herein relate to microelectromechanical systems (MEMS), and more particularly to MEMS resonator structures.

### Background Information

Microelectromechanical systems (MEMS) are small integrated devices or systems that combine electrical and mechanical components. The components can range in size from the sub-micrometer level to the millimeter level, and there can be any number, from one, to a few, to potentially thousands or millions, in a particular system. Some MEMS structures, in particular MEMS resonators, are hermetically sealed within low-pressure cavities to ensure consistent operation in different environments and temperature ranges. The resonance frequency of silicon MEMS resonators depends on temperature. For native silicon the temperature coefficient of frequency (TCF) is approximately 30 ppm/° C. In general, there will be a linear component (TCF1) and a quadratic component (TCF2). One method of passive temperature compensation involves doping the silicon crystal with n- or p-type dopants to reduce TCF2 and altering the resonant mode to minimize TCF1. One can compensate for any residual dependence of frequency on temperature by measuring the local temperature of the MEMS die and compensating for it using a frequency synthesizer such as a (phase-locked loop) PLL frequency synthesizer. One method of measuring the local MEMS temperature is to use a thermistor.

### SUMMARY

MEMS devices with co-packaged thermistors and methods of fabrication are described. In an embodiment, a method of fabricating a MEMS device with co-packaged thermistor includes etching a bottom cavity pattern into a support layer (e.g., commonly referred to as an epitaxial layer or device layer) of a silicon-on-insulator (SOI) wafer so that a plurality of separate islands protrude from a bottom surface of the bottom cavity pattern. A thermistor pattern, a thermistor plug input and a thermistor plug output can then be etched into the support layer of the SOI wafer, with thermistor plug input being coupled with a first end of the thermistor pattern and the thermistor plug output being coupled with a second end of the thermistor pattern. A device layer (e.g., MEMS device layer) is then bonded to top sides of the plurality of separate islands and patterned to form a resonator element, a thermistor via-device input, and a thermistor via-device output. Patterning of the device layer can be before or after bonding. This can be followed by bonding a cap layer to the device layer. The cap layer may include pre-formed structures including a thermistor via-cap input and a thermistor via-cap output, and optionally an out-of-plane drive electrode and anchor. As such, bonding the cap layer to the device layer includes bonding the thermistor via-cap input to the thermistor via-device input, bonding the thermistor via-cap output to the thermistor via-device output, and bonding the anchor to the resonator element. The out-of-plane drive electrode can be aligned directly over the resonator element. The fabrication sequence can then include the formation of a back-end-of-the-line (BEOL) build-up structure over the cap layer for device passivation, and electrical connection, followed by singulation.

In accordance with embodiments, the bonding operations may be wafer-to-wafer bonding and may be accomplished using suitable bonding techniques such as silicon-silicon or silicon-silicon oxide fusion bonding at high temperatures and pressure. The separate layers (e.g., wafers) can be pre-patterned prior to bonding or patterned after bonding depending upon the particular structures. In some embodiments, a suitable etching technique such as dry reactive ion etching (DRIE) is used. For example, the device layer may be etched after being wafer bonded to the support layer. This etching operation may optionally be supplemented by forming a mask layer, or etch stop layer, such as silicon oxide over the support layer to protect the underlying structures during etching of the device layer. In order to facilitate electrical connection between the thermistor via-device input and a thermistor via-device output of the device layer with the thermistor plug input and thermistor plug output, respectively, of the support layer a plurality of electrically conductive contacts (e.g., polysilicon plugs, etc.). In such a configuration, bonding the device layer to the top sides of the plurality of separate islands includes bonding the device layer directly to the silicon oxide mask layer and the plurality of electrically conductive contacts.

In an embodiment, a MEMS device with co-packaged thermistor includes a patterned support layer including a lower cavity and a thermistor pattern, with a portion of the thermistor pattern directly underneath the lower cavity, a device layer bonded to the patterned support layer, the device layer including a resonator element that is over the lower cavity, and a cap layer bonded to the device layer. The cap layer may optionally include an upper cavity over the resonator element. The patterned support layer can additionally include an anchor, with the resonator element being bonded to the anchor. The thermistor pattern can include a variety of patterns, such as a serpentine, zigzag, square shape, etc. that spans at least partially directly underneath the resonator element.

Integration of the thermistor pattern in the support layer can decouple doping requirements of the thermistor and device layer. In an embodiment, the patterned support layer has a dopant concentration less than or equal to a dopant concentration of the device layer. For example, the device layer may be homogenously doped with a dopant concentration on an order of 10¹⁹ cm⁻³ and higher, and the patterned support layer may be doped with a dopant concentration of 1×10¹⁵ to 5×10¹⁹ cm⁻³.

Wafer-level bonding sequences may be utilized to fabricate the MEMS devices with co-packaged thermistors. In an embodiment, the device layer is bonded directly to the patterned support layer with silicon-silicon bonding. In an embodiment, a mask layer (e.g., dielectric layer such as silicon oxide) and electrically conductive contacts (e.g., polysilicon plugs) are formed over the patterned support layer, and the device layer is bonded to the mask layer and electrically conductive contacts.

The patterned support layer may be formed of a variety of materials such as single crystalline silicon, polysilicon, and multiple-layer stacks. In an embodiment, the patterned support lays is a second device layer of a silicon-on-insulator (SOI) substrate.

Various in-plane and out-of-plane drive and sense electrodes can be arranged adjacent to and directly over the resonator element. In an embodiment, the cap layer (e.g., silicon) includes an out-of-plane drive electrode directly over the upper cavity. The device layer may also include an in-plane drive electrode laterally adjacent to the resonator element. The in-plane and out-of-plane drive electrodes may also be accompanied by corresponding sense electrodes.

The various MEMS components and/or connections can be defined by patterns of isolation trenches extending through the corresponding layers. In an embodiment, a first pattern of isolation trenches in the support layer defines the thermistor pattern, a thermistor plug input coupled with a first end of the thermistor pattern, and a thermistor plug output coupled with a second end of the thermistor pattern. A second pattern of isolation trenches in the device layer can further define the resonator element, an in-plane drive electrode, a thermistor via-device input, and a thermistor via-device output, for example. The thermistor via-device input may be bonded to the thermistor plug input, and the thermistor via-device output may be bonded to the thermistor plug output either directly, such as with silicon-silicon bonds, or with an intermediate mask layer and electrically conductive contacts. A third pattern of isolation trenches in the cap layer can further define an out-of-plane drive electrode directly over the resonator element, a thermistor via-cap input, and a thermistor via-cap output. The thermistor via-cap input may be bonded to the thermistor via-device input and the thermistor via-cap output may be bonded to the thermistor via-device output, for example with silicon-silicon bonds. Additional MEMS components and/or connections may also be formed in the various layers. The isolation trenches of the third pattern of isolation trenches may additionally be filled to provide hermetic scaling of the resonator cavity volume.

The co-packaged thermistors in accordance with embodiments may be electrically connected in a variety of manners, such as two-terminal connection and four-terminal connection. In an exemplary four-terminal connection an additional thermistor plug current input and thermistor plug current output are formed in the support layer, with the thermistor plug current input coupled with the first end of the thermistor pattern and the thermistor plug current output coupled with the second end of the thermistor pattern. Corresponding via connections (e.g., via interconnects) can then be formed in the overlying device layer and cap layer, for connection with a corresponding electrical contact terminal and chip contact pad of the BEOL build-up structure. In an exemplary two-terminal connection voltage can be borrowed from the surrounding structures. For example, a DC bias voltage applied to a chip contact pad and electrical contact terminal to the resonator element can also be electrically connected with a first end of the thermistor pattern.

### BRIEF DESCRIPTION OF THE DRAWINGS

FIG. 1 is an isometric view illustration of a MEMS device with rectangular resonator element in accordance with an embodiment.

FIGS. 2A-2B are isometric view illustrations of a MEMS device circular resonator element in accordance with an embodiment.

FIGS. 3A-3B are isometric view illustrations of a MEMS device rectangular resonator element in accordance with an embodiment.

FIGS. 4A-4B are schematic cross-sectional side view and isometric view illustration of an SOI wafer in accordance with an embodiment.

FIG. 5A is a schematic isometric view illustration of an SOI wafer with defined thermistor and device contacts in accordance with an embodiment.

FIG. 5B is a schematic cross-sectional side view illustration taken along line B-B of FIG. 5A in accordance with an embodiment.

FIG. 6A is a schematic isometric view illustration of an SOI wafer with thermistor pattern and isolated thermistor and device contacts in accordance with an embodiment.

FIG. 6B is a schematic cross-sectional side view illustration taken along line B-B of FIG. 6A in accordance with an embodiment.

FIG. 6C is a schematic isometric view illustration of an SOI wafer with hard mask formed over a thermistor pattern and isolated thermistor and device contacts in accordance with an embodiment.

FIG. 6D is a schematic isometric view illustration of an SOI wafer with a patterned hard mask layer that does not cover top surfaces of the patterned support layer in accordance with an embodiment.

FIG. 6E is a schematic isometric view illustration of an SOI wafer and patterned conductive layer formed over a thermistor pattern and isolated thermistor and device contacts in accordance with an embodiment.

FIG. 7A is a schematic isometric view illustration of a bonded device layer in accordance with an embodiment.

FIG. 7B is a schematic cross-sectional side view illustration taken along line B-B of FIG. 7A in accordance with an embodiment.

FIG. 8A is a schematic isometric view illustration of a bonded device layer including a patterned resonator element, electrodes and thermistor contacts in accordance with an embodiment.

FIG. 8B is a schematic cross-sectional side view illustration taken along line B-B of FIG. 8A in accordance with an embodiment.

FIG. 9A is a schematic isometric view illustration of a bonded cap layer with patterned via interconnects in accordance with an embodiment.

FIG. 9B is a schematic cross-sectional side view illustration taken along line B-B of FIG. 9A in accordance with an embodiment.

FIG. 10 is a schematic cross-sectional side view illustration of MEMS device with co-packaged thermistor in accordance with an embodiment.

FIG. 11 is a schematic cross-sectional side view illustration of MEMS device with co-packaged thermistor in accordance with an embodiment.

FIG. 12 is a circuit diagram of a two-terminal co-packaged thermistor in accordance with an embodiment.

FIG. 13 is a circuit diagram of a four-terminal co-packaged thermistor in accordance with an embodiment.

FIG. 14 is a schematic isometric view illustration of an SOI wafer with thermistor pattern and isolated two-terminal co-packaged thermistor and device contacts in accordance with an embodiment.

FIG. 15 is a schematic isometric view illustration of an SOI wafer with thermistor pattern and isolated four-terminal co-packaged thermistor and device contacts in accordance with an embodiment.

FIG. 16 is a schematic isometric view illustration of a bonded device layer including a patterned resonator element, electrodes and thermistor contacts for a four thermal co-packaged thermistor in accordance with an embodiment.

FIG. 17 is a schematic isometric view illustration of a bonded cap layer with patterned via interconnects for a four-terminal co-packaged thermistor in accordance with an embodiment.

### DETAILED DESCRIPTION

Embodiments describe MEMS devices and methods of fabrication including a co-packaged thermistor. In particular, a thermistor can be co-packaged with a resonator element to reduce thermal lag between the thermistor and the resonator element. In an embodiment, a MEMS device includes a patterned support layer including a lower cavity and a thermistor pattern, where a portion of a thermistor pattern is directly underneath the lower cavity. A device layer is bonded to the patterned support layer and patterned to include a resonator element that is over the lower cavity, and one or more in-plane drive electrodes laterally adjacent to the resonator element. A cap layer is additionally bonded to the device layer, where the cap layer may include an upper cavity over the resonator element and optionally one or more out-of-plane drive electrodes directly over the resonator element. Contacts to the thermistor pattern can be made using a series of isolated and stacked silicon via interconnects in the device layer and cap layer. The fabrication sequences described herein may be wafer-scale fabrication sequences in which a plurality of MEMS devices are fabricated and singulated from a processed wafer stack.

In one aspect, it has been observed that the high doping levels required in the device layer to compensate for TCF2 precludes the use of a thermistor in the device layer because this can render the thermistor pattern too conductive. In addition, it would consume extra die area, reducing the number of dies that can fit in a wafer and therefore increasing the fabrication cost per die. In another aspect, area may be limited within the space above a resonator element where out-of-plane drive and sense electrodes are included. Embodiments described herein address these challenges by using a silicon-on-insulator (SOI) wafer as the handle wafer and defining the thermistor pattern (thermistor element) in this wafer. This thermistor provides a local measure of temperature with good thermal coupling and is placed directly below the resonator element without increasing the die area. An SOI wafer is not required however, in some embodiments the thermistor pattern can be formed in a polysilicon or metal layer, or alternatively a polysilicon or metal layer formed over a patterned silicon layer.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “above”, “over”, “to”, “between”, “spanning” and “on” as used herein may refer to a relative position of one layer with respect to other layers. One layer “above”, “over”, “spanning” or “on” another layer or bonded “to” or in “contact” with another layer may be directly in contact with the other layer or may have one or more intervening layers. One layer “between” layers may be directly in contact with the layers or may have one or more intervening layers.

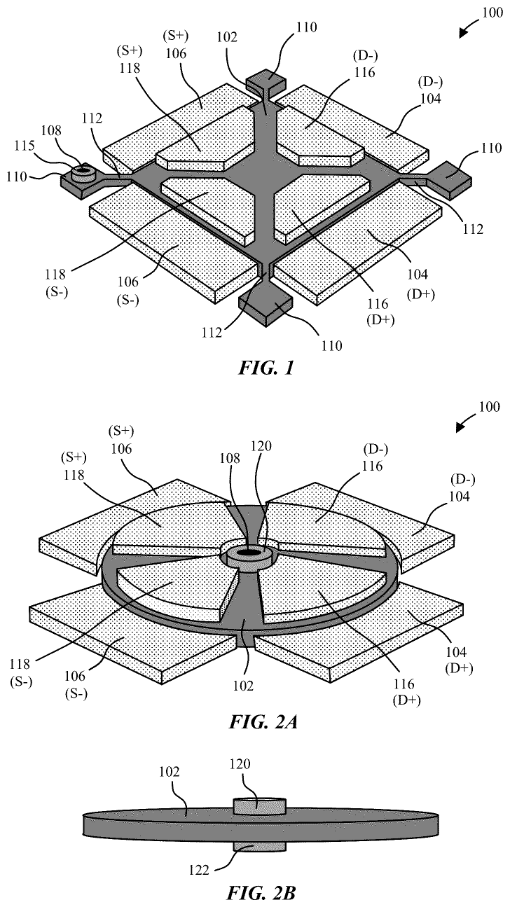

Referring now to FIG. 1, an isometric view illustration is provided of a MEMS device 100 with rectangular resonator element in accordance with an embodiment. As depicted, the square resonator element 102 may be part of a capacitively-transduced Lamé mode resonator including a pair of in-plane drive electrodes 104 denoted by D+/D− and a pair of in-plane sense electrodes 106 denoted by S+/S−, disposed around its periphery whilst the resonator element 102 itself is direct current (DC) biased through an electrical contact terminal 108 at one or more anchors 110. In this instance the anchors 110 are connected to corners of the resonator element 102 with tethers 112 and are coupled to the electrical contact terminal 108 through a via interconnect 115. Via interconnects can similarly be integrated for connecting with the various sense and drive electrodes, as well as thermistor structures as will described in more detail.

In operation, the two in-plane drive electrodes 104 are used to provide two drive signals that are 180° out of phase, as denoted D+/D−. Another set of in-plane sense electrodes 106, denoted S+/S−, are used to collect the two out of phase output signals and recombine them. A bias voltage can additionally be provided to the resonator element 102 through an electrical contact terminal 108. Typically, this would be used for frequency tuning.

The MEMS device 100 in accordance with embodiments may additionally include out-of-plane via drive electrodes 116 and out-of-plane via sense electrodes 118. For example, the out-of-plane via drive electrodes 116 and out-of-plane via sense electrodes 118 can be positioned over a top surface of the resonator element 102 and separated by a gap distance (such as 0.05-2.0 microns) for capacitive transduction of the resonator element 102. Similar to the in-plane drive electrodes 104 and in-plane sense electrodes 106, the out-of-plane via drive electrodes 116 and out-of-plane via sense electrodes 118 can be utilized to drive and collect out of phase signals and recombine them. The resonator element 102 may further be configured such that the in-plane drive electrodes 104 excites an in-plane resonance mode, and the out-of-plane via electrodes 116 excites an out-of-plane resonance mode in a controlled manner. Herein, “a controlled manner” refers to selectively exciting one, both or neither of the in-plane and out-of-plane resonance mode. For an in-plane resonance mode, the resonator element may be deflectable in plane into open space laterally around the resonator element. For an out-of-plane resonance mode the resonator element may be deflectable into the lower cavity and upper cavity.

Rather than tethering the resonator element 102 to anchors, the resonator element 102 can be supported by centrally located anchors. FIGS. 2A-2B are isometric view illustrations of a MEMS device circular resonator element 102 in accordance with an embodiment. In interest of clarity the various sense and drive electrodes are not illustrated in FIG. 2B. As shown, the resonator element 102 can be supported by one or more anchors 120, 122 on a top and/or bottom side of the resonator element 102. Similar to the capacitively-transduced resonator depicted in FIG. 1, the capacitively-transduced resonator depicted in FIG. 2A includes a pair of in-plane drive electrodes 104 denoted by D+/D− and a pair of in-plane sense electrodes 106 denoted by S+/S− disposed around its periphery whilst the resonator element 102 itself is DC biased through one or more anchors 120. The one or more anchors 120 may be physically connected with the resonator element 102 to provide physical support, and optionally function as a DC bias electrode. The one or more anchors 120 may also be physically connected with the resonator element 102 to provide physical support. Similar to FIG. 1, out-of-plane via drive electrodes 116 and out-of-plane via sense electrodes 118 may optionally be included above the resonator element 102 for out-of-plane driving and sensing.

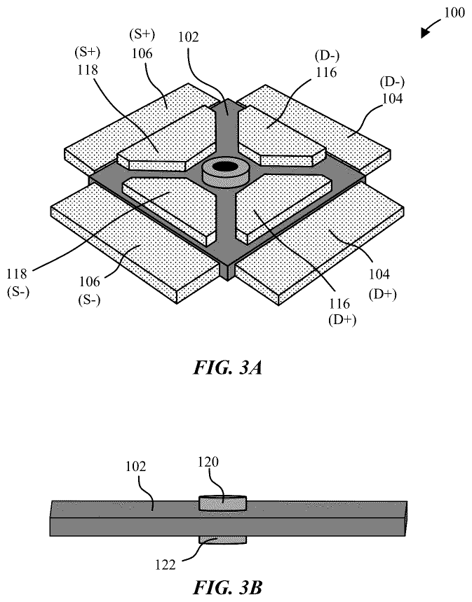

FIGS. 3A-3B are isometric view illustrations of a MEMS device circular resonator element 102 in accordance with an embodiment. In interest of clarity the various sense and drive electrodes are not illustrated in FIG. 3B. FIGS. 3A-3B are substantially similar to those of FIGS. 2A-2B, with only differences in shape/size of the features.

It is to be appreciated that the resonator structures illustrated in FIG. 1, FIGS. 2A-2B, and FIGS. 3A-3B are simplified illustrations of MEMS devices 100 in accordance with embodiments that include resonator elements 102 that are suspended within a hermetically sealed cavity maintained at low pressure. Furthermore, the figures are not necessarily drawn to scale. Embodiments are not limited to these specific structures and are applicable to a variety of MEMS devices, such as any bulk acoustic wave (BAW) or surface acoustic wave (SAW) resonator, etc. Different configurations with different electrode arrangements may be implemented without departing from the embodiments. Embodiments described herein may also be applicable to piezoelectrically-transduced resonators.

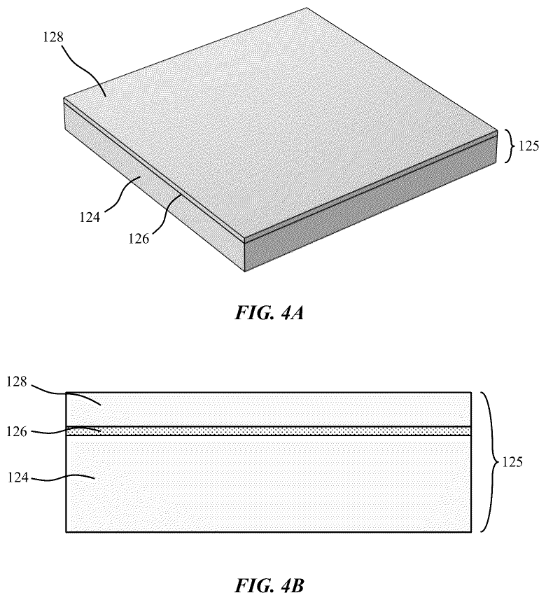

Referring now to FIGS. 4A-4B schematic cross-sectional side view and isometric view illustrations are provided of an SOI wafer 125 in accordance with an embodiment. As shown, the processing sequence may begin with an SOI wafer 125 including a handle wafer 124 (e.g., silicon wafer), a buried oxide layer 126, and support layer 128. For example, the support layer 128 may be a conventional device layer of an SOI wafer 125. It is to be appreciated however that embodiments are not limited to an SOI wafer, and instead can substitute the handle wafer 124 for any suitable handle substrate such as glass, silicon, etc., the buried oxide layer 126 can be any suitable insulating or dielectric layer (e.g., oxide, nitride, carbide, etc.), and the support layer 128 can be formed of a variety of materials including single crystalline silicon, polysilicon, etc. and may include multiple layers. In accordance with embodiments, the thickness of the support layer 128 may be 5-100 μm thick, for example, which may be thick enough to accommodate a bottom cavity and thickness of an underlying thermistor pattern. The support layer 128 may additionally be doped to control current flow. In an exemplary embodiment, the support layer 128 is formed of single crystalline silicon, and has a dopant concentration (p or n) of 1×10¹⁵ to 5×10¹⁹ cm⁻³, which may be the same or less than the dopant concentration of the device layer utilized to form the resonator element.

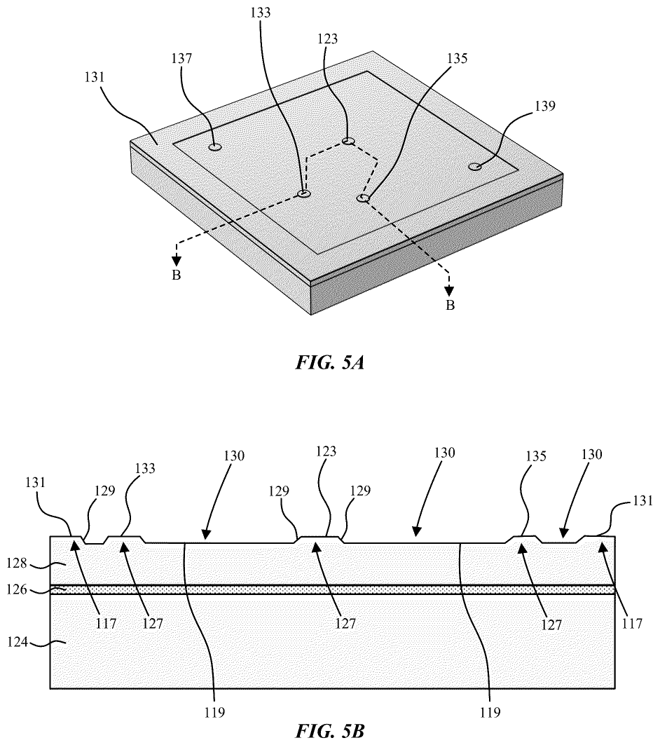

The support layer 128 can then be etched (or otherwise patterned) as shown in FIGS. 5A-5B to form a bottom cavity 130 pattern into the support layer 128 where a plurality of separate islands 127 protrude from a bottom surface 119 of the bottom cavity 130 pattern. Specifically, the schematic cross-sectional side view of FIG. 5B is taken along line B-B of the schematic isometric view illustrated in FIG. 5A. The etching or patterning can also form a bottom cavity seal 117 that protrudes from the bottom surface 119. As shown, the bottom cavity seal 117 can include a top cavity seal surface 131 and sidewalls 129. Likewise, the islands 127 can include sidewalls 129 and top surfaces depending upon functionality of the respective islands, such as a thermistor output surface 133, optional anchor top surface 123, and thermistor output surface 135. In an embodiment the lower cavity depth can be 0.05-50 μm deep from the top surfaces to the bottom surface 119. Sidewalls 129 may be straight or angled (as illustrated) and may be faceted along specific crystal planes depending upon etching technique/composition and crystal structure and orientation of the support layer 128, or may be smeared, as in the case of a local oxidation of silicon (LOCOS) process.

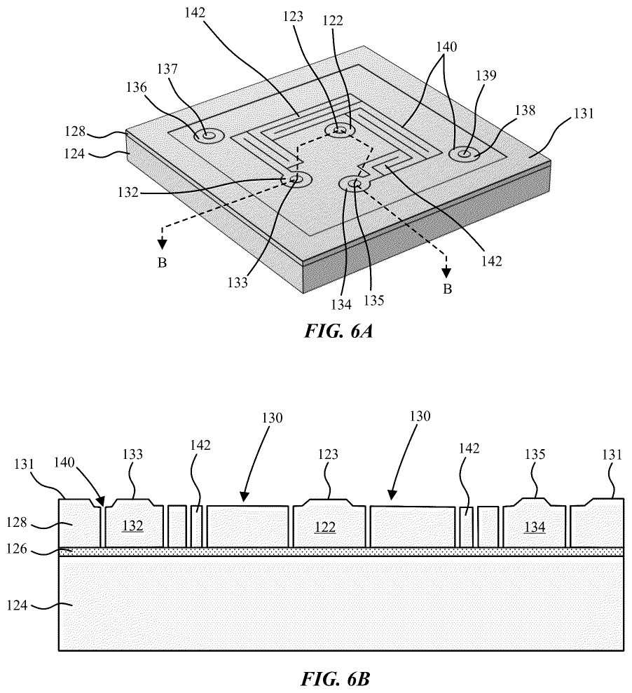

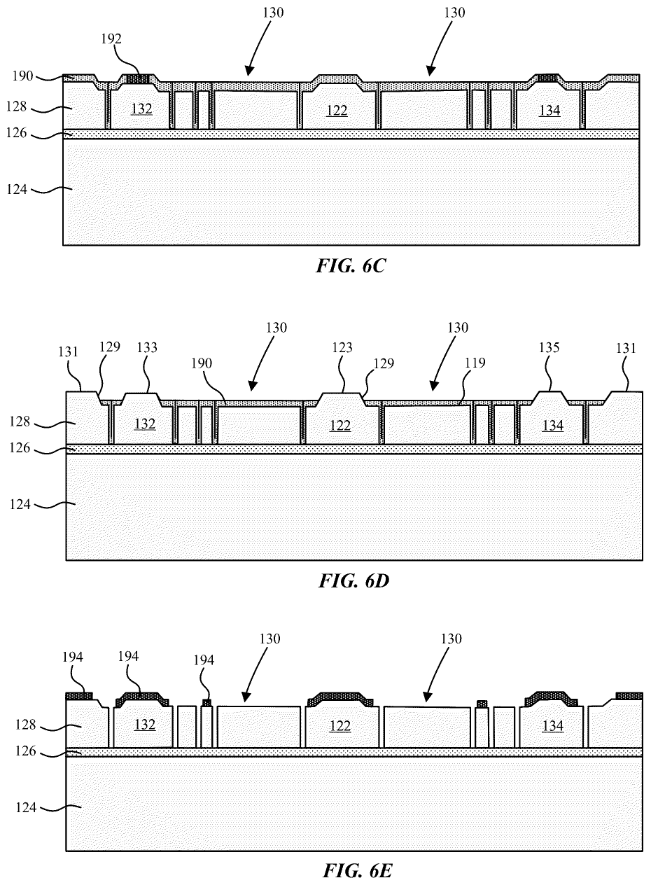

Referring now to FIGS. 6A-6B, a pattern of isolation trenches 140 can then be etched through the support layer 128 to form a thermistor pattern and device contacts. For example, etching may be DRIE. Etching may be performed completely through the support layer 128 and stop on the buried oxide layer 126 (or other suitable dielectric layer). As shown, the etched structure may include a thermistor plug input 132 coupled with a first end of a thermistor pattern 142, and a thermistor plug output 134 coupled with a second end of the thermistor pattern 142. The thermistor pattern 142 can be of a suitable width and thickness, as well as shape to achieve a determined resistance over temperature range. For example, the thermistor pattern 142 can be serpentine shaped (as shown), zigzag, rectangular, etc. The particular pattern may be adjusted to accommodate resistivity of the support layer material and sensitivity of the thermistor circuit. Additional contact plugs can also be formed in the support layer 128, such as a drive contact plug 136 (and drive contact surface 137) and sense contact plug 138 (and sense contact surface 139) as shown in FIG. 6A. The drive contact plug(s) 136 and sense contact plug(s) 138 may function as isolated support structures rather than to transfer charge elsewhere through the support layer 128. In the illustrated embodiment isolation trenches 140 can remain open, and unfilled.

Additional layers can optionally be formed over the support layer 128 for a variety of reasons, such to provide conductive paths or to function as a hard mask or etch stop layer during subsequent layer etch processes. For example, in the embodiment illustrated in FIG. 6C a blanket mask layer 190, such as silicon oxide, silicon nitride, etc. can be deposited or grown over the support layer 128 and at least partially or completely fill the isolation trenches 140. In order to provide electrical connection to the contact plugs and connected thermistor pattern 142 electrically conductive contacts 192, such as polysilicon or a metallic material such as a refractory metal alloy, can be formed through the mask layer 190 to contact the top surfaces of the islands 127 for the thermistor output and thermistor input. An electrically conductive contact 192 may optionally not be formed over the top surface 123 of the anchor 122, and similarly the top surfaces for the cavity seal 117, drive contact plug 136 and sense contact plug 138. Where mask layer 190 has a uniform thickness, the depth of the bottom cavities 130 is therefore transferred with the topography of the mask layer 190.

A mask layer 190 can also be deposited or grown while preserving the top surfaces of the patterned support layer for silicon-silicon bonding. For example, in the embodiment illustrated in FIG. 6D a mask layer 190 is deposited over the patterned support layer 128 and patterned to expose top cavity seal surfaces 131, thermistor input surface 133, top surface 123 of the anchor 122, and thermistor output surface 135. As shown, the mask layer 190 can partially or completely cover the bottom surface 119 of the bottom cavity 130, can partially or completely fill the isolation trenches 140, and may optionally partially span along the sidewalls 129 of the protruding features, which may be taller than a thickness of the mask layer 190.

Other layers may also optionally be formed. For example, patterned conductive layer 194 can optionally be formed over the patterned support layer 128 as shown in FIG. 6E. In such a configuration, the patterned conductive layer 194, such as a refractory metal or metal alloy, can be formed over the islands as well as the thermistor pattern 142. In such a configuration, the patterned conductive layer 194 can function as the thermistor element, and also provide the topography for bonding with a subsequent substrate. Suitable materials may also have a sufficient melting point to withstand downstream silicon-silicon fusion bonding operations. A variety of configurations are possible.

For clarity and conciseness, the following description and exemplary fabrication sequence is made with regard to the underlying structure of FIG. 6B, though it is to be appreciated that the fabrication sequences can also be combined with other underlying structures, such as FIGS. 6C and 6D, and modifications thereof.

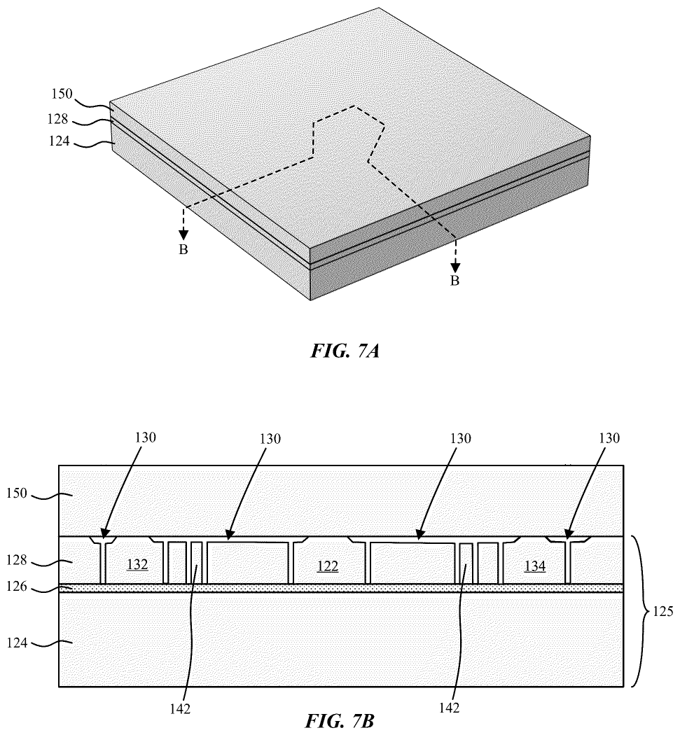

Referring now to FIGS. 7A-7B a device layer 150, such as a silicon wafer, can then be bonded to the underlying patterned support layer 128, or any intervening layer(s), for example with fusion bonding a silicon-silicon, silicon-silicon oxide, or metal-metal interface. Where the patterned support layer 128 includes a refractory metal or metal alloy layer, the device layer 150 may include a similarly patterned metal layer for metal-metal bonding. In an embodiment, the device layer 150 is a silicon wafer, which may optionally be doped. For example, the device layer 150 can be homogenously doped with a dopant concentration on the order of 10¹⁹ cm⁻³ and higher. The device layer 150 may be pre-processed to include various MEMS structures or processed after wafer bonding to for various MEMS structures such as resonators, humidity sensors, gas sensors, accelerometers, etc. as well as various contacts.

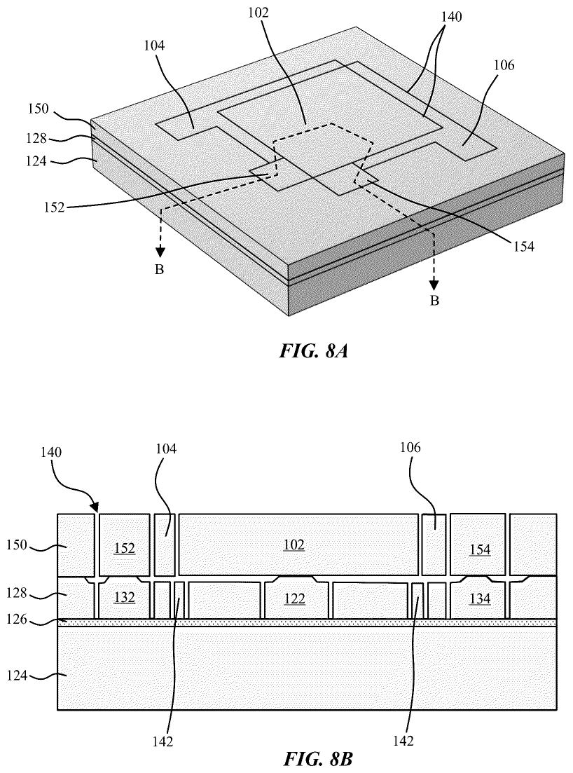

In the embodiment illustrated in FIGS. 8A-8B the device layer 150 is patterned to form a resonator element 102, a thermistor via-device input 152, and a thermistor via-device output 154. Additionally, the device layer 150 can be patterned to form one or more in-plane drive electrodes 104 and in-plane sense electrodes 106 laterally adjacent to the resonator element 102. In the particular embodiment illustrated the resonator element 102 is bonded to and is supported by the anchor 122. Alternatively, the device layer 150 can include tethers 112 and anchors 110, such as illustrated in FIG. 1. The device layer 150 is patterned after wafer bonding suitable etching techniques such as DRIE may be utilized to form isolation trenches 140. In such a fabrication sequence the underlying support layer 128 may optionally include mask layer 190 to protect the underlying structure during etching. In accordance with embodiments, the isolation trenches 140 within the device layer 150 may remain open, and unfilled, particularly to allow flexure of the resonator element 102.

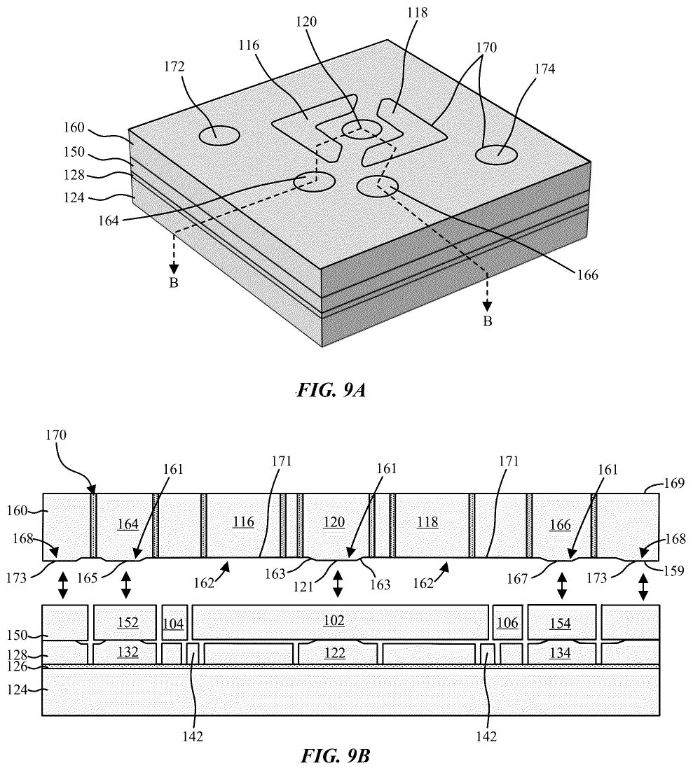

Referring now to FIGS. 9A-9B a cap layer 160 (e.g., patterned silicon wafer) can then be bonded to (e.g., directly to) the device layer 150, such as with fusion bonding to create silicon-silicon bonds, or with metallic bonding such as eutectic bonds and intermetallic bonds to reduce the maximum temperature the wafer is exposed to during processing. Similar to the support layer 128, the cap layer 160 can include a bottom surface 159 including a plurality of islands 161 and cavity seal 168 with sidewalls 163 protruding downward from top surface 171 of an upper cavity 162 pattern formed in a bottom surface of the cap layer 160. Sidewalls 163 may be straight or angled (as illustrated) and may be faceted along specific crystal planes depending upon etching technique/composition and crystal structure and orientation of the cap layer 160, or may be smeared. In an embodiment the upper cavity depth can be 0.05-2 μm deep from the top surface 171 to the bottom surface 159.

As shown, a pattern of isolation trenches 170 can also extend through a thickness of the cap layer 160. The isolation trenches 170 can be pre-formed in the cap layer 160 prior to being bonded to the device layer 150. Each isolation trench 170 may be partially or completely filled with a liner layer, such as silicon oxide, and may optionally be filled with a filler material, which can by anything conformal such as polysilicon, tetraethyl orthosilicate (TEOS)-oxide grown film, etc. to aid in hermetically sealing the cap layer 160, while also electrically isolating various MEMS components and/or connections. A top surface 169 of the cap layer 160 can include a planarized surface that is formed of (and spans) the top side of the cap layer 160 bulk material (e.g., silicon) and the top side of the isolation trenches 170 formed of the top side of the liner layer and top side of the optional filler material.

The isolation trenches 170 in accordance with embodiments can be utilized to define various MEMS components and/or connections. As shown, the isolation trenches 170 through the cap layer 160 can define a thermistor via-cap input 164 and a thermistor via-cap output 166. Additionally, the isolation trenches 170 can define one or more out-of-plane drive electrodes 116 and one or more out-of-plane via sense electrodes 118 that are wholly or at least partially directly over the resonator element 102, as well as one or more anchors 120. In this configuration, the depth of the upper cavity 162 defines the out-of-plane transduction gap. Isolation trenches 170 can additionally define one or more via drive inputs 172 and one or more via sense outputs 174 that can be electrically connected with the in-plane drive electrodes 104 and in-plane sense electrodes 106. As shown in FIG. 9B, the bottom surface 165 of the thermistor via-cap input 164 can be bonded directly to thermistor via-device input 152, the bottom surface 121 of the anchor 120 can be bonded directly to the resonator element 102, and the bottom surface 167 of the thermistor via-cap output 166 can be bonded directly to the thermistor via-device output 154. Additionally bottom surfaces 173 of the cap layer 160 can be bonded to the device layer 150 to form a top cavity seal around the upper cavity 162. In such an arrangement, the resonator element 102 is hermetically sealed in the cavity volume defined by the upper cavity 162 and bottom cavity 130.

At this stage BEOL processing can be formed over the planarized top surface 169 of the cap layer 160 to provide passivation and electrical routing. Further processing may then be formed, such as bonding to an integrated circuit wafer and/or singulation of multiple MEMS devices from the stacked wafer structure.

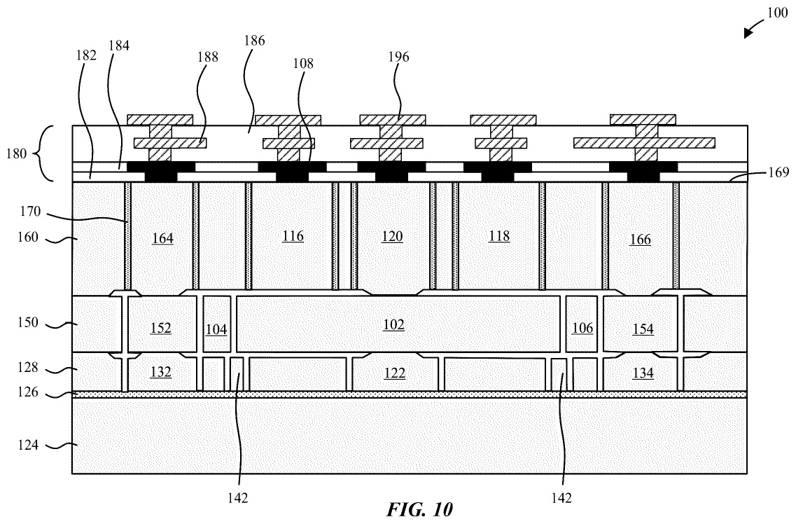

FIG. 10 is a schematic cross-sectional side view illustration of MEMS device 100 with co-packaged thermistor in accordance with an embodiment. In the particular embodiment illustrated, a BEOL build-up structure 180 is formed over the top surface 169 of the cap layer 160. As shown, the BEOL build-up structure 180 may include one or more passivation layers 182, 184. In an embodiment the first passivation layer 182 is a single layer or multiple layer stack that may be formed of one or more materials to mitigate small molecule diffusion, such as hydrogen, helium, etc. into the cavity volume. Exemplary materials include insulating materials such as silicon nitride, aluminum nitride, aluminum oxide, or silicon carbide to prevent shorting across the top surface 169. Additional layers can also be included such as aluminum, copper, titanium, nickel, gold, chromium, molybdenum, titanium nitride, metal silicide, polysilicon, etc. to assist in blocking diffusion. The top passivation layer 184 may be formed a suitable dielectric material such as silicon oxide used for BEOL structures to provide electrical insulation, film quality, and deposition rate. In particular, when the passivation layer 182 is formed of a high-stress nitride that cannot be deposited thick enough to provide sufficient dielectric insulation of metal traces, adding the optional top passivation layer 184 can provide improved dielectric insulation.

Openings may then be formed through the one or more passivation layers 182, 184 to expose the various MEMS components and/or connections followed by deposition of electrical contact terminals 108. For example, the electrical contact terminals 108 can be formed on the thermistor via-cap input 164, one or more out-of-plane via drive electrodes 116, anchor 120, one or more out-of-plane via sense electrodes 118, and thermistor via-cap output 166 as shown. Electrical contact terminals 108 can additionally be formed on one or more via drive inputs 172 and one or more via sense outputs 174 for in-plane driving and sensing.

The electrical contact terminals 108 may be formed of one or more layers including various metal layers and alloys thereof, polysilicon, etc. Selection of materials may additionally depend upon doping concentrations cap layer. For example, a first liner layer of heavily doped polysilicon (e.g., intrinsically doped polysilicon, ISDP) can first be deposited directly onto an n-type silicon cap layer to avoid creating a p-n junction. This can be followed by depositing one or more bulk metal layers, such as copper, gold, etc. An intermediate polysilicon layer may not be necessary for making electrical contact with p-type silicon. A variety of arrangements are possible.

Additional BEOL processing can be performed following the formation of the electrical contact terminals 108, such as the formation additional dielectric layer 186 and wiring layers 188 connected to chip contact pads 196.

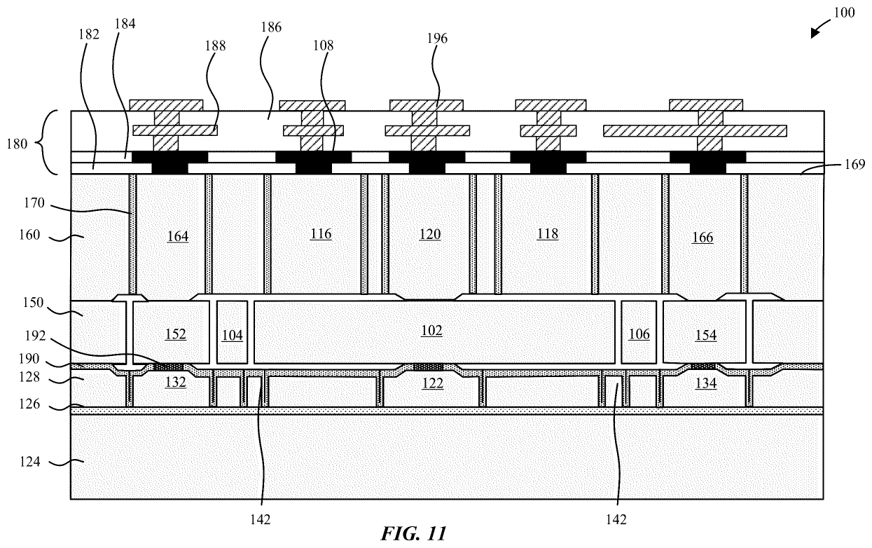

FIG. 11 is a schematic cross-sectional side view illustration of MEMS device 100 with co-packaged thermistor in accordance with an embodiment. The MEMS device of FIG. 11 is similar to that of FIG. 10 with one difference being the formation of mask layer 190 and conductive contacts 192 on the support layer 128, similar to that described and illustrated with regard to FIG. 6C. In this configuration, the device layer 150 is bonded directly to the mask layer 190 and conductive contacts 192. A variety of configurations are possible, inclusive of at least the patterned metal layer of FIG. 6D.

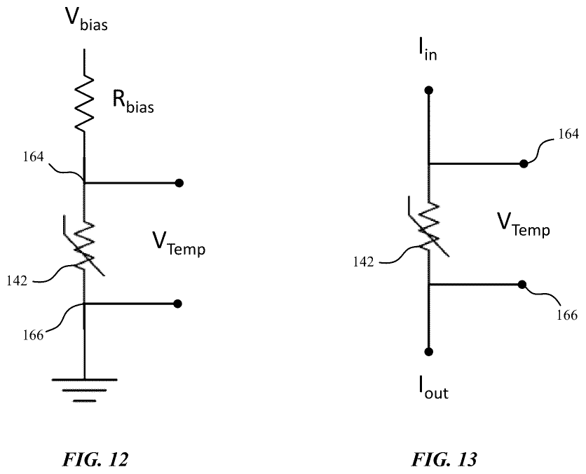

Referring now to FIG. 12 and FIG. 13 circuit diagrams are provided for two-terminal and four-terminal co-packaged thermistors, respectively. In each embodiment, the terminals are made with reference to connections made within cap layer 160. Both circuit diagrams operate in accordance with a similar basic principle in that that voltage can be measured across opposite ends of the thermistor pattern 142 through thermistor via-cap input 164 and thermistor via-cap output 166. Specifically, the thermistor via-cap input 164 is bonded to the thermistor via-device input 152 which is bonded to thermistor plug input 132 which is physically connected with a first end of the thermistor pattern 142. Similarly, the via-cap output 166 is bonded to the thermistor via-device output 154 which is bonded to thermistor plug output 134 which is physically connected with a second end of the thermistor pattern 142.

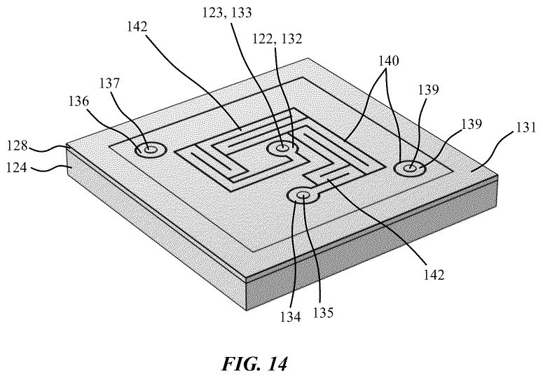

In order to measure voltage across the thermistor pattern 142, a reference voltage or current is supplied. In one embodiment, a reference voltage is supplied by an electrical contact terminal 108 that is DC biased. In one implementation the reference voltage bias (Vbias), resistance bias (Rbias), ground, and voltage differential measurement (Vtemp) are all provided in a controller, such as an application specific integrated circuit (ASIC) or system on chip die. The reference voltage bias can also by shared within the MEMS structure. For example, the electrical contact terminal 108 coupled with anchor 120, can also provide a reference voltage for the thermistor. Referring now to FIG. 14, a schematic isometric view illustration is provided of an SOI wafer with thermistor pattern and isolated two-terminal co-packaged thermistor and device contacts in accordance with an embodiment. The support layer 128 is patterned similar to that previously described and illustrated with regard to FIG. 6A with consolidation of features. As shown, anchor 122 can also function as the thermistor plug input 132, with top surface 123 of the anchor 122 thus also functioning as thermistor input surface 133. In such a configuration a first end of the thermistor pattern 142 would be electrically connected with the resonator element 102 to be formed. Thus, all connections through the resonator element can also function as a thermistor connection, providing space savings. Similar modifications would thus be implemented for subsequent layers. It is to be appreciated that these are exemplary connections, and embodiments are not so limited.

In an exemplary four-terminal configuration separate current inputs and outputs are provided to the thermistor pattern 142. Exemplary four-terminal co-packaged thermistor designs are illustrated and described with regard to FIGS. 14-16, which illustrate variations of the two-terminal co-packaged thermistor designs of FIGS. 6A, 8A, and 9A.

FIG. 15 is a schematic isometric view illustration of an SOI substrate with thermistor pattern and isolated four-terminal co-packaged thermistor and device contacts in accordance with an embodiment. FIG. 15 is similar to that of FIG. 6A with the addition of both thermistor plug current input 202 and thermistor plug input 132 coupled with the first end of a thermistor pattern 142, and both thermistor plug current output 204 and thermistor plug output 134 coupled with the second end of the thermistor pattern 142.

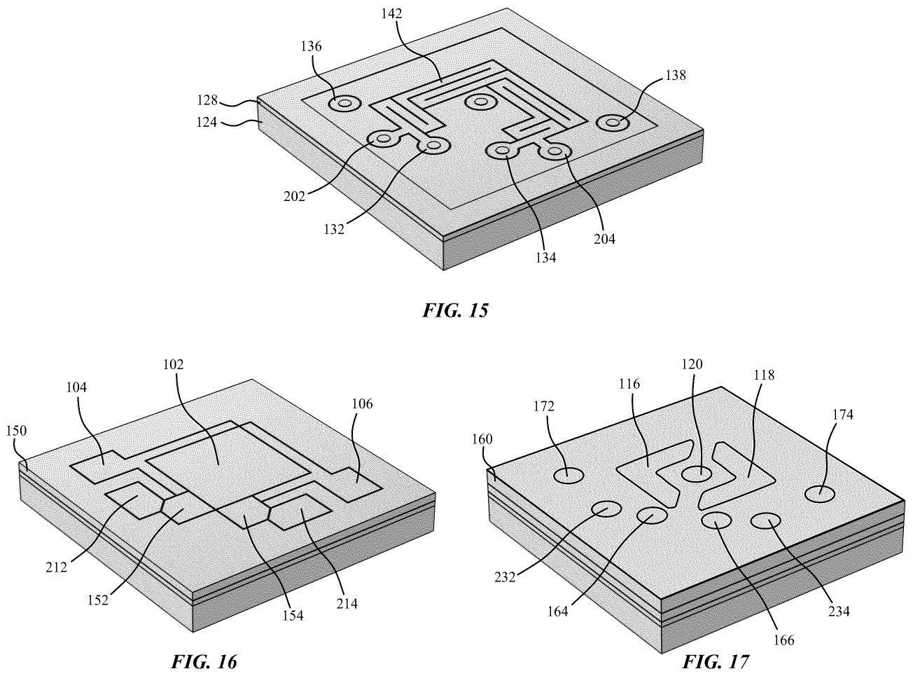

FIG. 16 is a schematic isometric view illustration of a bonded device layer including a patterned resonator element, electrodes and thermistor contacts for a four thermal co-packaged thermistor in accordance with an embodiment. FIG. 16 is similar to that of FIG. 8A with the addition of thermistor via-device current input 212, and a thermistor via-device current output 214.

FIG. 17 is a schematic isometric view illustration of a bonded cap layer with patterned via interconnects for a four-terminal co-packaged thermistor in accordance with an embodiment. FIG. 17 is similar to that of FIG. 9A with the addition of thermistor via-cap current input 232 and a thermistor via-cap current output 234.

While not separately illustrated it is to be appreciated that BEOL build-up structure 180 would additionally include electrical contact terminals 108 and chip contact pads 196 to provide current input and output to the four-terminal co-packaged thermistor.

In utilizing the various aspects of the embodiments, it would become apparent to one skilled in the art that combinations or variations of the above embodiments are possible for forming a MEMS resonator with co-packaged thermistor. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration. Furthermore, it is to be appreciated that the figures have been provided for illustrational purposes and may not be to scale. Also, in the interest of conciseness and reducing the total numbers of figures, a given figure may be used to illustrate the features of more than one aspect of the disclosure, and not all elements in the figure may be required for a given aspect.

What is claimed is:

1. A MEMS device with co-packaged thermistor comprising:
a patterned support layer including a lower cavity and a thermistor pattern, a portion of the thermistor pattern directly underneath the lower cavity;
a device layer bonded to the patterned support layer, the device layer including a resonator element over the lower cavity; and
a cap layer bonded to the device layer.

2. The MEMS device of claim 1, wherein the patterned support layer includes an anchor, and the resonator element is bonded to the anchor.

3. The MEMS device of claim 1, wherein the thermistor pattern comprises a serpentine shape that spans at least partially directly underneath the resonator element.

4. The MEMS device of claim 1, wherein the patterned support layer includes a thermistor input surface and a thermistor output surface, and the device layer is bonded to the thermistor input surface and the thermistor output surface.

5. The MEMS device of claim 1, wherein the device layer is homogenously doped with a dopant concentration on an order of 10¹⁹ cm⁻³ and higher, and the patterned support layer is doped with a dopant concentration of 1×10¹⁵ to 5×10¹⁹ cm⁻³.

6. The MEMS device of claim 1, wherein the patterned support layer and the device layer are both doped, and the patterned support layer has a dopant concentration that is less than or equal to a dopant concentration of the device layer.

7. The MEMS device of claim 1, wherein the device layer is bonded directly to the patterned support layer with silicon-silicon bonds.

8. The MEMS device of claim 1, further comprising a mask layer and electrically conductive contacts over the patterned support layer, wherein the device layer is bonded to the mask layer and electrically conductive contacts.

9. The MEMS device of claim 1, wherein the patterned support layer is a second device layer of a silicon-on-insulator substrate.

10. The MEMS device of claim 1, wherein the cap layer further includes an upper cavity over the resonator element an out-of-plane drive electrode directly over the upper cavity.

11. The MEMS device of claim 10, wherein the device layer further includes an in-plane drive electrode laterally adjacent to the resonator element.

12. The MEMS device of claim 11, wherein the resonator element is configured such that the in-plane drive electrode excites an in-plane resonance mode, and the out-of-plane drive electrode excites an out-of-plane resonance mode in a controlled manner.

13. The MEMS device of claim 1, further comprising a first pattern of isolation trenches in the patterned support layer, wherein the first pattern of isolation trenches defines the thermistor pattern, a thermistor plug input coupled with a first end of the thermistor pattern, and a thermistor plug output coupled with a second end of the thermistor pattern.

14. The MEMS device of claim 13:
further comprising a second pattern of isolation trenches in the device layer, the second pattern of isolation trenches defining the resonator element, an in-plane drive electrode, a thermistor via-device input, and a thermistor via-device output;
wherein the thermistor via-device input is bonded to the thermistor plug input, and the thermistor via-device output is bonded to the thermistor plug output.

15. The MEMS device of claim 14:
further comprising a third pattern of isolation trenches in the cap layer, the third pattern of isolation trenches defining an out-of-plane drive electrode directly over the resonator element, a thermistor via-cap input, and a thermistor via-cap output;
wherein the thermistor via-cap input is bonded to the thermistor via-device input, and the thermistor via-cap output is bonded to the thermistor via-device output.

16. The MEMS device of claim 15, wherein the isolation trenches of the third pattern of isolation trenches are filled.

17. The MEMS device of claim 13, further comprising a thermistor plug current input coupled with the first end of the thermistor pattern, and a thermistor plug current output coupled with the second end of the thermistor pattern.

18. The MEMS device of claim 13, wherein the first end of the thermistor pattern is electrically connected with the resonator element.

19. The MEMS device of claim 18, wherein the resonator element is electrically connected with a direct current (DC) bias electrical contact terminal.

20. The MEMS device of claim 19, wherein the second end of the thermistor pattern is electrically connected with ground.

21. A method of fabricating a MEMS device with co-packaged thermistor comprising:
etching a bottom cavity pattern into a support layer of a silicon-on-insulator (SOI) wafer, wherein a plurality of separate islands protrude from a bottom surface of the bottom cavity pattern;
etching a thermistor pattern, a thermistor plug input and a thermistor plug output into the support layer of the SOI wafer, wherein the thermistor plug input is coupled with a first end of the thermistor pattern and the thermistor plug output is coupled with a second end of the thermistor pattern;
bonding a device layer to top sides of the plurality of separate islands;
patterning the device layer to form a resonator element, a thermistor via-device input, and a thermistor via-device output;
bonding a cap layer to the device layer, the cap layer including a thermistor via-cap input and a thermistor via-cap output, wherein the thermistor via-cap input is bonded to the thermistor via-device input, and the thermistor via-cap output is bonded to the thermistor via-device output; and
forming a BEOL build-up structure over the cap layer.

22. The method of claim 21, wherein the cap layer includes an out-of-plane drive electrode; and bonding the cap layer to the device layer comprises bonding an anchor to the resonator element, wherein the out-of-plane drive electrode is directly over the resonator element.

23. The method of claim 21, further comprising forming a mask layer over the support layer.

24. The method of claim 23, further comprising forming a plurality of electrically conductive contacts in the mask layer directly over the plurality of islands, wherein bonding the device layer to the top sides of the plurality of separate islands comprises bonding the device layer directly to the mask layer and the plurality of electrically conductive contacts.

25. The method of claim 23, further comprising bonding the device layer to top cavity seal surfaces 131 of a cavity seal when bonding the device layer to the top sides of the plurality of separate islands.
